(19) United States
(12) Patent Application Publication
(10) Pub. No.: US 2021/0150087 A1
(43) Pub. Date: May 20, 2021

(54) METHODS, SYSTEMS, AND MEDIA FOR DATA VISUALIZATION AND NAVIGATION OF MULTIPLE SIMULATION RESULTS IN URBAN DESIGN

(71) Applicant: Sidewalk Labs LLC, New York, NY (US)

(72) Inventors: Brian Ho, New York, NY (US); Dan Vanderkam, Brooklyn, NY (US); Douwe Osinga, New York, NY (US); Violet Whitney, Long Island City, NY (US); Kabir Soorya, Long Island City, NY (US); Jack Amadeo, Brooklyn, NY (US); Difei Chen, New York, NY (US); Okalo Ikhena, New York, NY (US); Amanda Meurer, Brooklyn, NY (US); Samara Trilling, New York, NY (US)

(21) Appl. No.: 16/951,639

(22) Filed: Nov. 18, 2020

Related U.S. Application Data
(60) Provisional application No. 62/936,843, filed on Nov. 18, 2019.

(51) Int. Cl. G06F 30/13; G06F 30/20; G06F 16/957

(52) U.S. Cl. CPC G06F 30/13; G06F 16/9577; G06F 30/20

(57) ABSTRACT

Methods, systems, and media for data visualization and navigation of multiple simulation results in urban design are provided. In some embodiments, the method comprises: generating, using a hardware processor, a plurality of design options for a district in response to running a simulation using a set of received design inputs; determining, using the hardware processor, a plurality of output values of the simulation for each parameter of a plurality of parameters that are associated with each of the plurality of design options; generating, using the hardware processor, a plurality of histograms, wherein each histogram corresponds to a parameter from the plurality of parameters associated with each of the plurality of design options; presenting, using the hardware processor, a user interface that includes the plurality of histograms, wherein one or more portions of each histogram in the user interface are user-selectable; in response to receiving a user selection of a portion within a histogram corresponding to a parameter, presenting, using the hardware processor, the user selection of the portion in the histogram of the user interface and determining one or more output values of the parameter that correspond with the portion of the histogram from the plurality of output values; and, in response to determining the one or more output values of the parameter that correspond with the portion of the histogram, automatically modifying, using the hardware processor, a presentation of remaining histograms in the user interface to highlight a first subset of output values of other parameters in the remaining histograms that correspond with the one or more output values of the parameter and reduce an appearance of a second subset of output values of the other parameters in the remaining histograms that do not correspond with the one or more output values of the parameter.

### CROSS-REFERENCE TO RELATED APPLICATIONS

This application claims the benefit of U.S. Provisional Patent Application No. 62/936,843, filed Nov. 18, 2019, which is hereby incorporated by reference herein in its entirety.

### TECHNICAL FIELD

The disclosed subject matter relates to methods, systems, and media for data visualization and navigation of multiple simulation results in urban design. More particularly, the disclosed subject matter relates to an interactive presentation of simulation results in urban design in which a user can modify one or more parameters within a simulation result and can filter, browse, and/or search through the simulation results.

### BACKGROUND

An urban planner or designer may run simulations to plan a city, town, or other geographic area. For example, a designer may run simulations that include different values of different variables, such as amounts of green space, sizes of buildings, densities of buildings, etc. Such simulations can yield different outputs, such as an amount of exposure to outdoor light, locations and intensities of wind tunnel effects created by buildings, etc. However, with simulations that include multiple parameters, each with multiple possible values that are simulated, and multiple outputs, it can be difficult to visualize simulation results.

Accordingly, it is desirable to provide new methods, systems, and media for data visualization and navigation of multiple simulation results in urban design.

### SUMMARY

Methods, systems, and media for data visualization and navigation of multiple simulation results in urban design are provided.

In accordance with some embodiments of the disclosed subject matter, a method for data visualization and navigation of multiple simulation results in urban design is provided, the method comprising: generating, using a hardware processor, a plurality of design options for a district in response to running a simulation using a set of received design inputs; determining, using the hardware processor, a plurality of output values of the simulation for each parameter of a plurality of parameters that are associated with each of the plurality of design options; generating, using the hardware processor, a plurality of histograms, wherein each histogram corresponds to a parameter from the plurality of parameters associated with each of the plurality of design options; presenting, using the hardware processor, a user interface that includes the plurality of histograms, wherein one or more portions of each histogram in the user interface are user-selectable; in response to receiving a user selection of a portion within a histogram corresponding to a parameter, presenting, using the hardware processor, the user selection of the portion in the histogram of the user interface and determining one or more output values of the parameter that correspond with the portion of the histogram from the plurality of output values; and, in response to determining the one or more output values of the parameter that correspond with the portion of the histogram, automatically modifying, using the hardware processor, a presentation of remaining histograms in the user interface to highlight a first subset of output values of other parameters in the remaining histograms that correspond with the one or more output values of the parameter and reduce an appearance of a second subset of output values of the other parameters in the remaining histograms that do not correspond with the one or more output values of the parameter.

In some embodiments, determining the plurality of output values further comprises querying a database of simulation outputs associated with each of the plurality of parameters.

In some embodiments, the user interface comprises an option to select a subset of parameters from the plurality of parameters for generating the plurality of histograms.

In some embodiments, each histogram in the plurality of histograms is generated using a t-distributed stochastic neighbor embedding technique.

In some embodiments, the user selection of the portion within the histogram is a user-selected point that corresponds to an output value within the histogram.

In some embodiments, the user selection of the portion within the histogram is a user-selected window that spans across multiple output values within the histogram.

In some embodiments, the method further comprises: receiving a second user selection of a second portion within a second histogram corresponding to a second parameter; presenting the second user selection of the second portion in the second histogram corresponding to the second parameter and determining a third subset of output values of the second parameter from the first subset of output values in the second histogram of the second parameter that correspond with the second portion of the second histogram; and automatically modifying the presentation of the remaining histograms in the user interface based on the third subset of output values of the second parameter.

In accordance with some embodiments of the disclosed subject matter, a system for data visualization and navigation of multiple simulation results in urban design is provided, the system comprising a memory and a hardware processor that, when configured to execute computer executable instructions stored in the memory, is configured to: generate a plurality of design options for a district in response to running a simulation using a set of received design inputs; determine a plurality of output values of the simulation for each parameter of a plurality of parameters that are associated with each of the plurality of design options; generate a plurality of histograms, wherein each histogram corresponds to a parameter from the plurality of parameters associated with each of the plurality of design options; present a user interface that includes the plurality of histograms, wherein one or more portions of each histogram in the user interface are user-selectable; in response to receiving a user selection of a portion within a histogram corresponding to a parameter, present the user selection of the portion in the histogram of the user interface and determining one or more output values of the parameter that correspond with the portion of the histogram from the plurality of output values; and, in response to determining the one or more output values of the parameter that correspond with the portion of the histogram, automatically modify a presentation of remaining histograms in the user interface to highlight a first subset of output values of other parameters in the remaining histograms that correspond with the one or more output values of the parameter and reduce an appearance of a second subset of output values of the other parameters in the remaining histograms that do not correspond with the one or more output values of the parameter.

In accordance with some embodiments of the disclosed subject matter, a non-transitory computer-readable medium containing computer executable instructions that, when executed by a processor, cause the processor to perform a method for data visualization and navigation of multiple simulation results in urban design is provided, the method comprising: generating, using a hardware processor, a plurality of design options for a district in response to running a simulation using a set of received design inputs; determining, using the hardware processor, a plurality of output values of the simulation for each parameter of a plurality of parameters that are associated with each of the plurality of design options; generating, using the hardware processor, a plurality of histograms, wherein each histogram corresponds to a parameter from the plurality of parameters associated with each of the plurality of design options; presenting, using the hardware processor, a user interface that includes the plurality of histograms, wherein one or more portions of each histogram in the user interface are user-selectable; in response to receiving a user selection of a portion within a histogram corresponding to a parameter, presenting, using the hardware processor, the user selection of the portion in the histogram of the user interface and determining one or more output values of the parameter that correspond with the portion of the histogram from the plurality of output values; and, in response to determining the one or more output values of the parameter that correspond with the portion of the histogram, automatically modifying, using the hardware processor, a presentation of remaining histograms in the user interface to highlight a first subset of output values of other parameters in the remaining histograms that correspond with the one or more output values of the parameter and reduce an appearance of a second subset of output values of the other parameters in the remaining histograms that do not correspond with the one or more output values of the parameter.

In accordance with some embodiments of the disclosed subject matter, a system for data visualization and navigation of multiple simulation results in urban design is provided, the system comprising: means for generating a plurality of design options for a district in response to running a simulation using a set of received design inputs; means for determining a plurality of output values of the simulation for each parameter of a plurality of parameters that are associated with each of the plurality of design options; means for generating a plurality of histograms, wherein each histogram corresponds to a parameter from the plurality of parameters associated with each of the plurality of design options; means for presenting a user interface that includes the plurality of histograms, wherein one or more portions of each histogram in the user interface are user-selectable; in response to receiving a user selection of a portion within a histogram corresponding to a parameter, means for presenting the user selection of the portion in the histogram of the user interface and determining one or more output values of the parameter that correspond with the portion of the histogram from the plurality of output values; and, in response to determining the one or more output values of the parameter that correspond with the portion of the histogram, means for automatically modifying a presentation of remaining histograms in the user interface to highlight a first subset of output values of other parameters in the remaining histograms that correspond with the one or more output values of the parameter and reduce an appearance of a second subset of output values of the other parameters in the remaining histograms that do not correspond with the one or more output values of the parameter.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 shows an example of a process for data visualization and navigation of multiple simulation results in urban design in accordance with some embodiments of the disclosed subject matter.

FIGS. 2A and 2B show examples of data visualizations in accordance with some embodiments of the disclosed subject matter.

FIG. 3 shows a schematic diagram of an illustrative system suitable for implementation of mechanisms described herein for data visualization and navigation of multiple simulation results in urban design in accordance with some embodiments of the disclosed subject matter.

FIG. 4 shows a detailed example of hardware that can be used in a server and/or a user device of FIG. 3 in accordance with some embodiments of the disclosed subject matter.

FIGS. 5A, 5B, 5C, 5D, 5E, 5F, 5G, 5H, and 5I show examples of data visualizations in accordance with some embodiments of the disclosed subject matter.

### DETAILED DESCRIPTION

In accordance with various embodiments, mechanisms (which can include methods, systems, and media) for data visualization and navigation of multiple simulation results in urban design are provided.

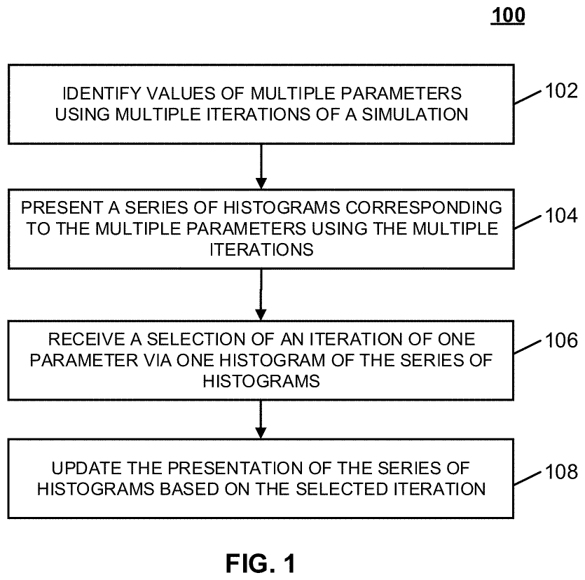

In some embodiments, the mechanisms described herein can present visualizations of results of simulations. In some embodiments, the mechanisms can present results of simulations in any suitable manner. For example, as described below in connection with FIG. 1, in some embodiments, the mechanisms can present a series of histograms that include the results of the urban design simulations. As a more particular example, in some embodiments, each histogram in a series of histograms can correspond to a different parameter of a simulation, where values plotted within the histogram correspond to values of the parameter associated with different iterations of the simulation. As a specific example, in an instance where a simulation is of a city, urban area, or other geographic location, and where parameters correspond to input parameters such as a density of buildings and output parameters such as a predicted comfort level of residents, the mechanisms can present a series of histograms, where a first histogram indicates different input values of the density of buildings that were used during different iterations of the simulation and where a second histogram indicates different output values of the predicted comfort level of residents over different iterations of the simulation (e.g., using different input values of the density of buildings, and/or any other suitable input values). Note that, in some embodiments, the mechanisms described herein can use any suitable algorithm(s) or models in connection with a simulation.

In some embodiments, the mechanisms can allow a user of a user device that presents visualizations of results of simulations to navigate through results of simulations. For example, in an instance where the mechanisms cause a series of histograms to be presented, the mechanisms can receive a selection of a particular value of one parameter via a corresponding histogram of the series of histograms. In some embodiments, the mechanisms can then use any suitable visual selection technique(s) to update other histograms in the series of histograms to highlight corresponding iterations. As a more particular example, continuing with the example described above, in an instance where a user of a user device selects an iteration of an input parameter of a density of buildings corresponding to a particular value (e.g., 50% density, 60% density, and/or any other suitable density value), the mechanisms can identify a corresponding value for an output parameter of a predicted comfort level of residents with the selected building density value. Continuing with this example, the mechanisms can then update the series of histograms to highlight the identified value of the predicted comfort level of residents within the corresponding histogram. As a specific example, in some embodiments, the mechanisms can cause the identified value to be highlighted in any suitable manner within the histogram (e.g., with a box or circle drawn around the identified value, with the identified value presented in a different color, and/or in any other suitable manner).

Turning to FIG. 1, an illustrative example 100 of a process for data visualization is shown in accordance with some embodiments of the disclosed subject matter. In some embodiments, blocks of process 100 can be executed on any suitable device, such as a user device running a simulation, and/or any other suitable device.

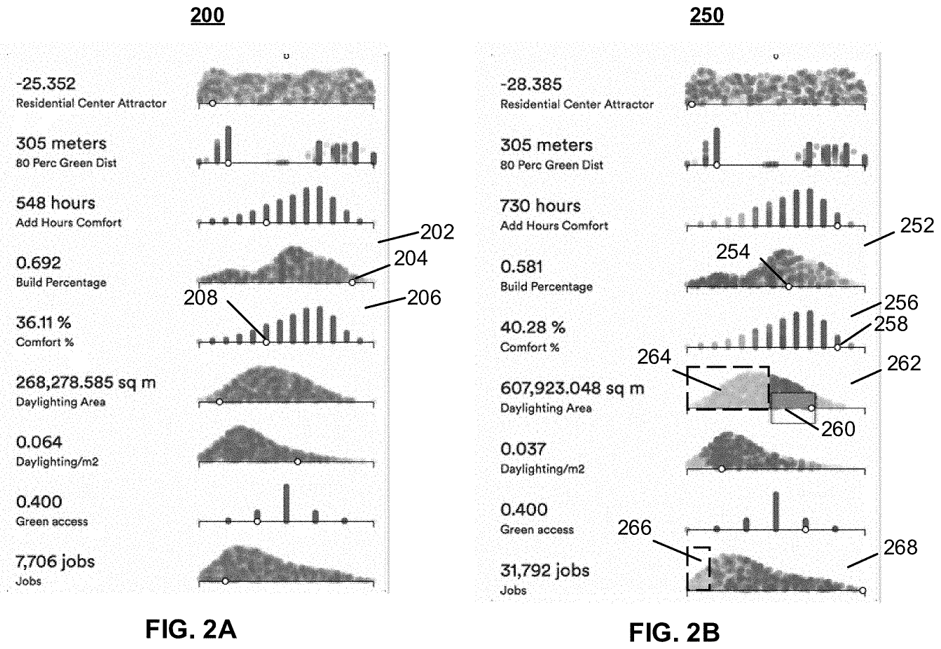

Process 100 can begin at 102 by identifying values of multiple parameters using multiple iterations of a simulation. In some embodiments, parameters of a simulation can include any suitable inputs and/or outputs of a simulation. For example, as shown in user interfaces 200 and 250 of FIGS. 2A and 2B, parameters of a simulation can include inputs to a simulation such as a density of buildings within a geographic location, a maximum height of buildings constructed within the geographic location, an amount of space dedicated to parks or playgrounds within the geographic location, and/or any other suitable inputs. As another example, as shown in user interfaces 200 and 250 of FIGS. 2A and 2B, parameters of a simulation can include outputs of a simulation, such as a predicted comfort level of residents of the geographic location, an average amount of daylight or outdoor light per unit area, and/or any other suitable output(s). Note that, in some embodiments, output values of a simulation can be calculated or generated using any suitable calculations or algorithms as part of the simulation. In some embodiments, each iteration of the simulation can include output values for any suitable output parameters for a particular combination of input values. For example, in some embodiments, a first iteration of the simulation can correspond to a first value of building density and a first value of maximum building height with corresponding output values for any suitable output parameters that are calculated using the input values of the first iteration, and a second iteration of the simulation can correspond to a second value of building density and a second value of maximum building height with corresponding output values for any suitable output parameters that are calculated using the input values of the second iteration.

In some embodiments, process 100 can identify the values of the multiple parameters over multiple iterations in any suitable manner. For example, in some embodiments, process 100 can identify outputs of different runs of a simulation, where each run corresponds to a different set of values for a group of input parameters. In some embodiments, process 100 can identify the outputs in any suitable manner, for example, by querying a database that stores simulation outputs, and/or in any other suitable manner. Note that, in some embodiments, outputs identified by process 100 can be generated by any suitable number of simulations or models. For example, in some embodiments, an output value that indicates a predicted comfort level of residents of a geographic location can be generated using a first model, and an output value that indicates an average amount of daylight or outdoor light can be generated using a second model. In some embodiments, any suitable algorithms or combination of algorithms can be used to generate output values.

At 104, process 100 can present a series of histograms corresponding to the multiple parameters using the multiple iterations. Examples of series of histograms are shown in user interfaces 200 and 250 of FIGS. 2A and 2B. For example, as illustrated in FIGS. 2A and 2B, the series of histograms can include values from 8 simulated parameters (“residential center attractor,” “80 perc green dist,” “add hours comfort,” “build percentage,” “comfort %,” “daylighting area,” “daylighting/m²,” “green access,” and “jobs”).

In some embodiments, the series of histograms can be presented in any suitable manner. For example, in some embodiments, the series of histograms can be presented in a user interface on a user device (e.g., a user device that runs a simulation, a user device that requests results from a simulation, and/or any other suitable user device). As another example, in some embodiments, the series of histograms can be presented in a three-dimensional manner. As a more particular example, in some embodiments, each histogram in the series of histograms can be presented as a layer in a three-dimensional stack of histograms. In some such embodiments, the three-dimensional stack of histograms can be manipulated in any suitable manner. For example, in some embodiments, the stack of histograms can be rotated around any suitable axis. As another example, in some embodiments, a histogram from the stack of histograms can be selected and highlighted in any suitable manner (e.g., to appear larger and/or closer than other histograms in the stack of histograms, and/or highlighted in any other suitable manner). Note that, in some embodiments, the series of histograms can use any suitable color scheme or pattern to indicate any suitable values of the histograms.

Additionally, note that, in some embodiments, each histogram in the series of histograms can use any suitable binning technique(s) to generate the histogram. For example, in some embodiments, each histogram can use bins of different sizes.

Note that, in some embodiments, the histograms or graphs can be generated using any suitable data visualization technique. For example, in some embodiments, histograms can be generated for values of a particular parameter using any suitable technique (e.g., t-distributed stochastic neighbor embedding, or t-SNE, and/or any other suitable technique(s)) that models a high-dimensional parameter as a two- or three-dimensional value. As a more particular example, within each histogram in the series of histograms, a particular location for each point in the histogram can be determined such that points that are close to each other represent iterations of the parameter that are relatively similar in a higher-dimensional space, and, conversely, points that are relatively far from each other represent iterations of the parameter that are relatively dissimilar in the higher-dimensional space. Additionally, note that, as described below in more detail in connection with blocks 106 and 108, individual points of an individual histogram can be selectable.

At 106, process 100 can receive a selection of one or more iterations of one parameter via one histogram of the series of histograms. In some embodiments, process 100 can receive the selection in any suitable manner. For example, in some embodiments, process 100 can receive a selection of a portion of a histogram of the series of histograms that indicates the one iteration of the one parameter. As a more particular example, referring to FIG. 2A, process 100 can receive a selection of a particular value 204 of a histogram 202 that indicates a particular iteration that corresponds to value 204 (e.g., that used value 204 as an input value, that generated value 204 as an output value, and/or any other suitable iteration). In some embodiments, the selection can be received via any suitable input device, such as selection with a mouse, selection on a touchscreen, and/or in any other suitable manner.

Note that, in some embodiments, a portion of a histogram that spans multiple values can be visually selected. For example, referring to FIG. 2B, in some embodiments, process 100 can receive a selection of a window 260 of histogram 262. As illustrated, window 260 can include any suitable number of values within histogram 262.

In some embodiments, selection of a point (or selection of a window that includes multiple points) within a histogram can cause the value corresponding to the point and to the parameter associated with the histogram from which the point was selected to be retrieved and/or identified. In some embodiments, the value of the selected points can be presented in the location of the selected point. Alternatively, in some embodiments, a marker (e.g., an open circle, a filled circle, and/or any other suitable marker) can be placed in the location of the selected point to indicate the selected point. Note that, in an instance in which a window that corresponds to multiple points of the histogram is selected, a rectangle that indicates that selected window can be presented that indicates the selection. Additionally, in an instance in which a window that corresponds to multiple points of the histogram is selected, points within the selection can be presented in a first visual manner (e.g., in color, and/or in any other suitable manner), and points that are not included within the selection can be presented in a second visual manner (e.g., grayed out, and/or in any other suitable manner). Note that, as described below in connection with block 108, selection of a point or a window within a particular histogram can cause the values associated with the parameter corresponding to the particular histogram to be filtered. For example, in an instance in which a window is selected by a user by drawing a rectangle to span a portion of a histogram, values associated with the parameter corresponding to the histogram can be filtered such that values that fall within the selected rectangle are identified or retrieved.

At 108, in response to receiving the selection of one or more iterations of one parameter, process 100 can update the presentation of the series of histograms based on the selected iteration. For example, in some embodiments, process 100 can update the histograms in the series of histograms to highlight values associated with the same iteration as the selected iteration. As a more particular example, in an instance where value 204 of histogram 202 is selected, process 100 can update the series of histograms such that value 208 (which can correspond to the same iteration as the iteration of the simulation that generated value 204 of histogram 202) of histogram 206 is highlighted. As a specific example, referring to FIG. 2A, histogram 202 can correspond to an input parameter that indicates a percentage of the geographic location that includes buildings, and value 204 can correspond to a particular value of the input parameter (e.g., 0.692%, as shown in FIG. 2A). Continuing with this example, in some embodiments, process 100 can identify a value of histogram 206 that corresponds to an output parameter (e.g., a predicted comfort level), such as output value 208, that is calculated using input value 204 for the input parameter of the percentage of the geographic location that includes buildings. Note that FIG. 2B shows an updated series of histograms that can be presented in response to selection of a different iteration. For example, in some embodiments, the series of histograms shown in FIG. 2B can be presented in response to a determination that value 254 of histogram 252 has been selected. As a more particular example, in some embodiments, the series of histograms can be updated such that value 258 of histogram 256 is highlighted.

In some embodiments, process 100 can highlight the corresponding iterations of each histogram in the series of histograms in any suitable manner. For example, in some embodiments, process 100 can cause values associated with the corresponding iterations to be colored within each histogram in a different color. As a more particular example, a color or a shade of a value can indicate a relative level of the value in an iteration relative to values in other iterations. As a specific example, in some embodiments, a histogram can have values that are colored such that lower values are colored in blue shades and higher values are colored in red shades. Note that, in some embodiments, colors or color mappings can be specified in any suitable manner. For example, in some embodiments, selection of a particular histogram within a series of histograms can cause a settings interface to be presented that allows a user to specify one or more colors that are to be applied to values of the histograms. As another example, in some embodiments, process 100 can cause any suitable outline to be drawn around values associated with the corresponding iterations of each histogram. As a more particular example, in some embodiments, process 100 can cause a box or a circle to be drawn around the values associated with the corresponding iterations of each histogram.

Note that, in some embodiments, process 100 can cause any suitable portions of histograms in the series of histograms to be grayed out or otherwise marked as being irrelevant based on the selection received at block 106, as shown in FIG. 2B. For example, as described above in connection with block 106, in some embodiments, process 100 can receive a selection of a window of a histogram, such as window 260 of histogram 262, as shown in FIG. 2B. Continuing with this example, in some embodiments, selection of window 260 can cause a portion of histogram 262 not included in window 260 to be grayed out, such as grayed out portion 264 of histogram 264. In some embodiments, process 100 can then update other histograms in the series of histograms to additionally gray out portions of the histograms corresponding to iterations not included in window 260. For example, as shown in FIG. 2B, histogram 268 can be updated such that portion 266 is grayed out.

Note that, in some embodiments, selection of one or more iterations at block 106 can cause an update of a block of data that is being represented by the histograms. In some embodiments, the updated block of data can then be accessed by process 100 to update the presentation of the histograms at block 108. For example, in some embodiments, visual selection of one or more iterations of a parameter at block 106 can be treated by process 100 as similar to generation of a query (e.g., a database query, and/or any other suitable query). That is, in some embodiments, selection of one or more iterations via a histogram, as described above in connection with block 106, can be treated as visual generation of a database query. In some embodiments, selection of one or more iterations via a histogram can cause the data represented by the histogram to be filtered to retrieve selected iterations and/or values of a parameter corresponding to selected iterations. Continuing with this example, in some embodiments, selection of the one or more iterations of the parameter at block 106 can cause process 100 to, at block 108, filter data represented in the other histograms in a series of histograms such that values associated with iterations corresponding to the selected iteration(s) are retrieved.

Additionally, note that, in some embodiments, a particular iteration that is selected or a particular iteration that is identified as corresponding to a selected iteration may not have a value. In some embodiments, process 100 can present histograms that include value-less iterations (that is, partial results) in any suitable manner. For example, in some embodiments, process 100 can indicate iterations that do not have a value with any suitable marker or visual representation (e.g., an empty circle, an X, and/or in any suitable manner). As another example, in some embodiments, in an instance in which a first parameter includes a value for a selected iteration and a second parameter does not include a value for the selected iteration, process 100 can cause values associated with the selected iteration to not be presented for any parameter.

Note that, in some embodiments, process 100 can use any suitable visual selection technique(s) to identify corresponding iterations (e.g., corresponding values) to a selected iteration. Additionally, in some embodiments, process 100 can use any suitable jitter and/or smoothing kernel(s) to identify corresponding iterations and/or values of corresponding iterations. For example, in some embodiments, process 100 can use any suitable jitter and/or smoothing kernel(s) to identify corresponding iterations and/or values of corresponding iterations for parameters that are discontinuous.

In some embodiments, identifying corresponding iterations can include rewriting or modifying a generated query to indicate that iterations or values within a particular range of a discontinuous parameter are to be identified. As a more particular example, in an instance where a particular iteration of a continuous parameter is selected, process 100 can use any suitable smoothing technique to identify a corresponding iteration of a discontinuous parameter. Continuing with the analogy given above in which the selection of one or more iterations as described in block 106 is similar to generation of a query, in some embodiments, identifying corresponding iterations using jitter and/or smoothing kernel(s) can be considered similar to rewriting the query generated by selection of the iteration(s).

Note that, in some embodiments, in instances in which data is being collected and/or added, process 100 can update a presentation of the histograms in real-time and/or in near real-time. For example, in some embodiments, process 100 can update histograms in a series of histograms to include newly collected data values for each parameter. In some embodiments, process 100 can cause newly added data values to be marked visually in any suitable manner. For example, in some embodiments, representations of newly added values can be colored with a different color relative to other values, and/or marked in any other suitable manner.

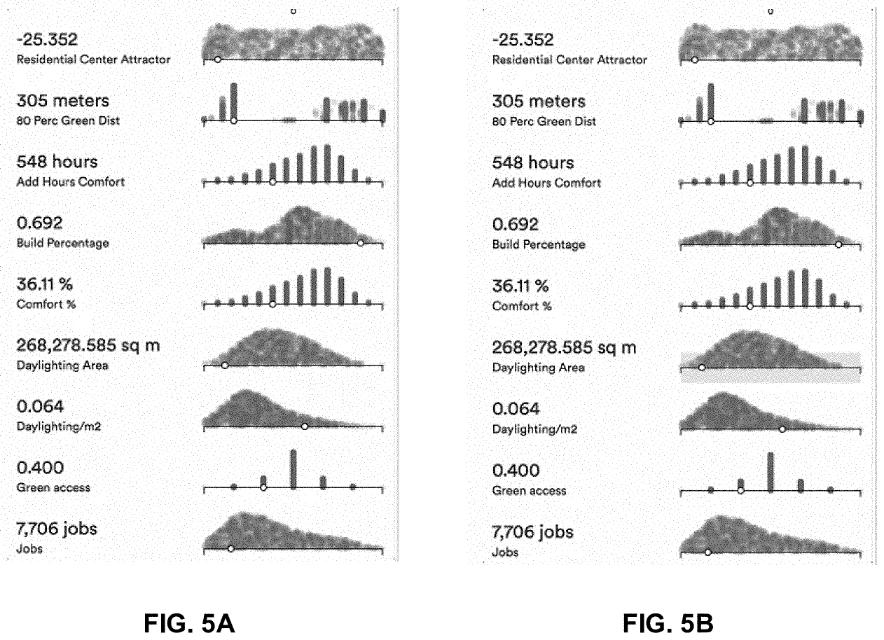

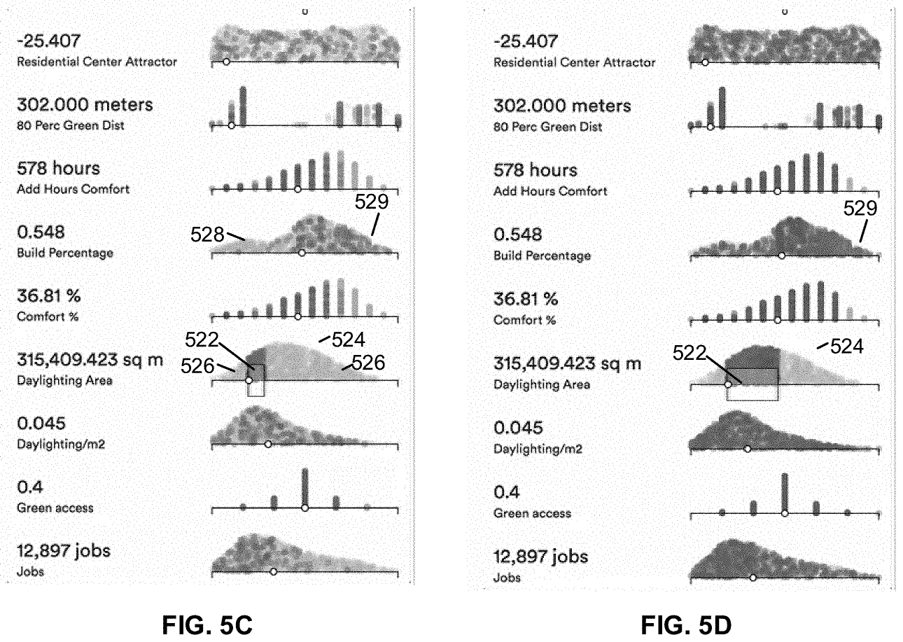

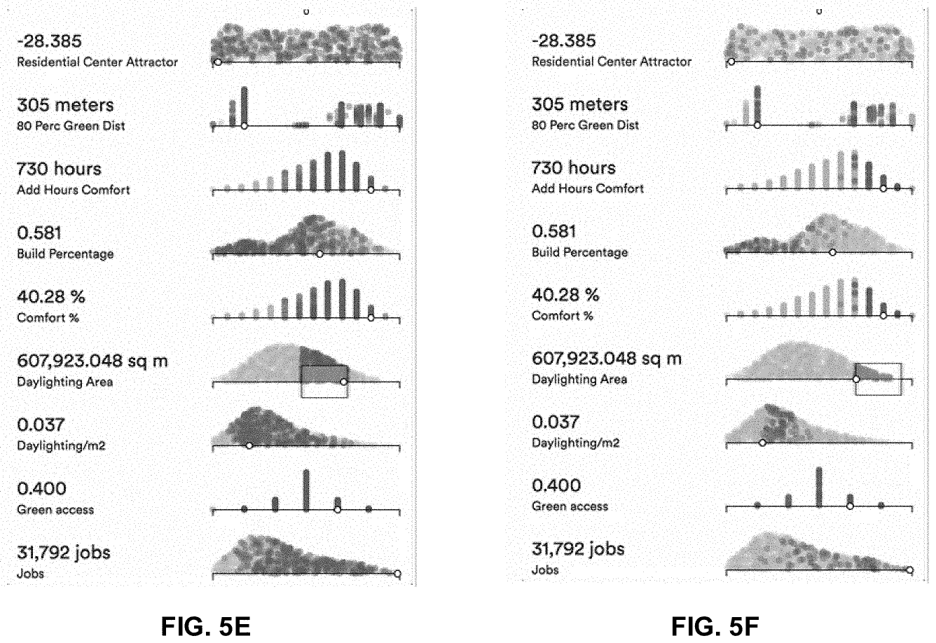

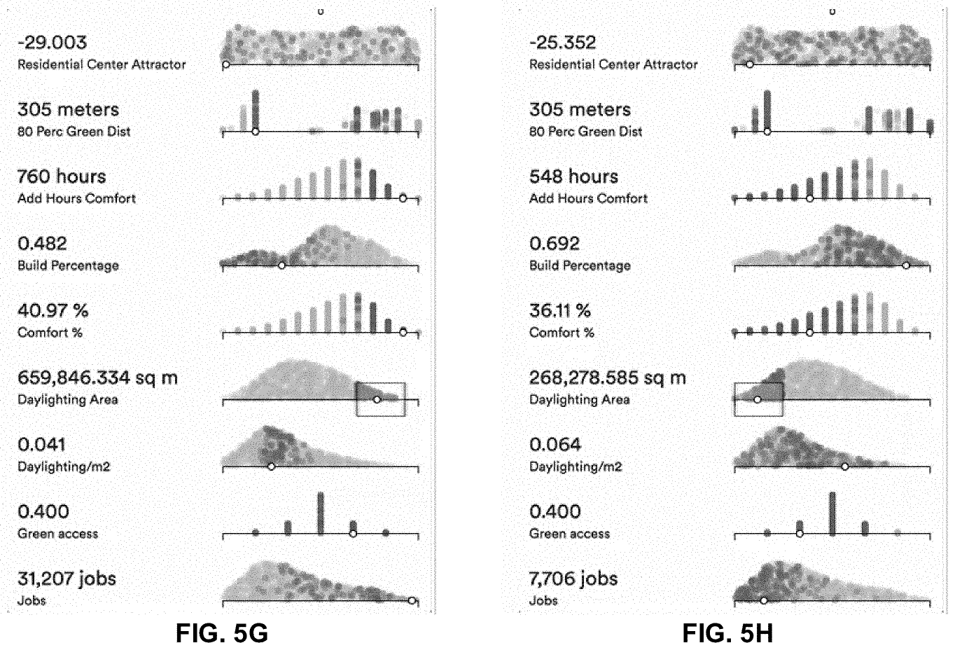

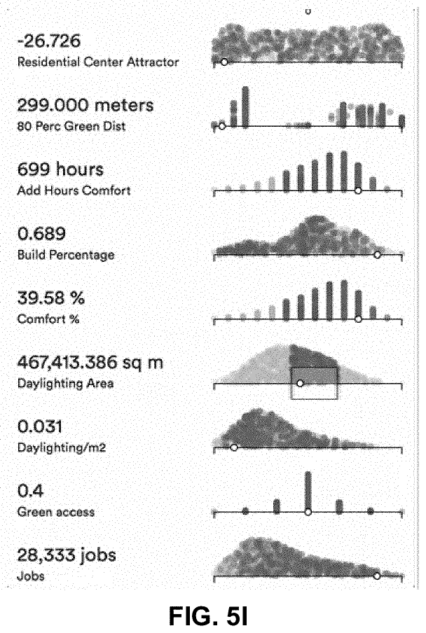

Turning to FIGS. 5A, 5B, 5C, 5D, 5E, 5F, 5G, 5H, and 5I, additional visualizations of data are shown in accordance with some embodiments of the disclosed subject matter. In particular, note that FIGS. 5A, 5B, 5C, 5D, 5E, 5F, 5G, 5H, and 5I show additional examples of selections of one or more iterations of a particular parameter via a histogram, and updates to other histograms in series of histograms based on the selected one or more iterations, as described above in connection with blocks 106 and 108 of FIG. 1. For example, FIGS. 5C and 5D illustrate updating representations of data in a series of histograms based on selected iterations in one histogram. As a more particular example, referring to FIG. 5C, selection of a window 522 of a histogram 524 can cause a non-selected portion of histogram 524 (e.g., iterations not represented in window 522) to be grayed out (e.g., portions 526 of histogram 524). Additionally, as described above, selection of window 522 of histogram 524 can cause process 100 to identify corresponding iterations associated with other parameters represented by the histograms in the series of histograms shown in FIG. 5C. In particular, the identified iterations associated with the other parameters can be highlighted, and iterations that do not correspond to the selected iterations (e.g., to iterations in window 522) can be grayed out (e.g., grayed out portion 528 of histogram 529). That is, in some embodiments, selection of window 522 within histogram 524 can cause process 100 to identify iterations corresponding to iterations represented within window 522, and can cause presentation of the data in each of the other histograms to be automatically updated based on the selected window 522.

Continuing with this example, and referring to FIG. 5D, in an instance in which window 522 is modified (e.g., made larger, as shown in FIG. 5D, made smaller, and/or modified in any other suitable manner), histogram 524, as well as the other histograms shown in the series of histograms, can be automatically updated based on the modified window. For example, the grayed out portions of histogram 524 can be updated based on the modification of window 522, as shown in FIG. 5D. As another example, in some embodiments, a visual representation of the data in each of the other histograms in the series of histograms can be modified based on the modification of window 522. As a more particular example, as shown in FIG. 5D, modification of window 522 to include more iterations (by enlarging window 522) can cause a smaller portion, or fewer data points, of histogram 524 to be grayed out. Correspondingly, as shown in FIG. 5D, inclusion of more iterations in window 522 can cause fewer data points in histogram 529 to be grayed out.

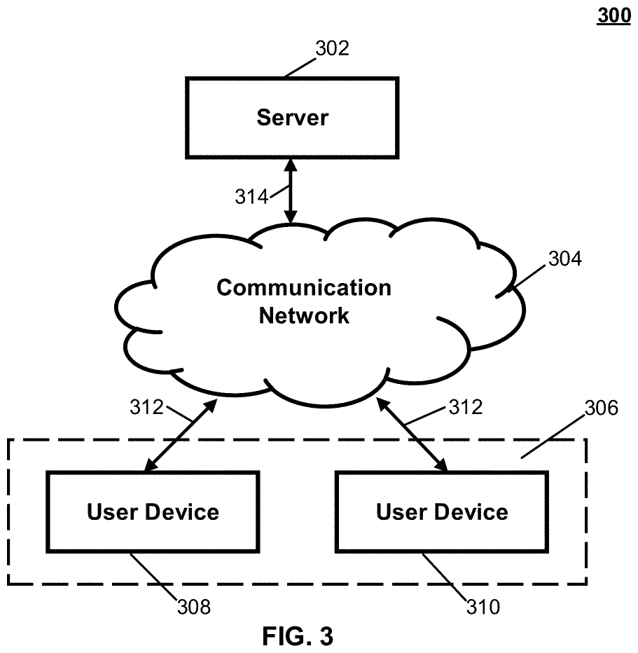

Turning to FIG. 3, an example 300 of hardware for data visualization and navigation of multiple simulation results in urban design that can be used in accordance with some embodiments of the disclosed subject matter is shown. As illustrated, hardware 300 can include a server 302, a communication network 304, and/or one or more user devices 306, such as user devices 308 and 310.

Server 302 can be any suitable server(s) for storing information, data, programs, and/or any other suitable content. For example, in some embodiments, server 302 can store data used to execute a simulation and/or data that is a result of a simulation that is used to generate a series of histograms. As another example, in some embodiments, server 302 can store any suitable programs or algorithms used to execute a simulation. Note that, in some embodiments, server 302 can be omitted.

Communication network 304 can be any suitable combination of one or more wired and/or wireless networks in some embodiments. For example, communication network 304 can include any one or more of the Internet, an intranet, a wide-area network (WAN), a local-area network (LAN), a wireless network, a digital subscriber line (DSL) network, a frame relay network, an asynchronous transfer mode (ATM) network, a virtual private network (VPN), and/or any other suitable communication network. User devices 306 can be connected by one or more communications links (e.g., communications links 312) to communication network 304 that can be linked via one or more communications links (e.g., communications links 314) to server 302. The communications links can be any communications links suitable for communicating data among user devices 306 and server 302 such as network links, dial-up links, wireless links, hard-wired links, any other suitable communications links, or any suitable combination of such links.

User devices 306 can include any one or more user devices suitable for executing a simulation, presenting a series of histograms that indicate results of one or more simulations, and/or performing any other suitable functions. In some embodiments, user devices 306 can include any suitable type(s) of user devices. For example, in some embodiments, user devices 306 can include a mobile phone, a tablet computer, a laptop computer, a desktop computer, and/or any other suitable type of user device.

Although server 302 is illustrated as one device, the functions performed by server 302 can be performed using any suitable number of devices in some embodiments. For example, in some embodiments, multiple devices can be used to implement the functions performed by server 302.

Although two user devices 308 and 310 are shown in FIG. 3 to avoid over-complicating the figure, any suitable number of user devices, and/or any suitable types of user devices, can be used in some embodiments.

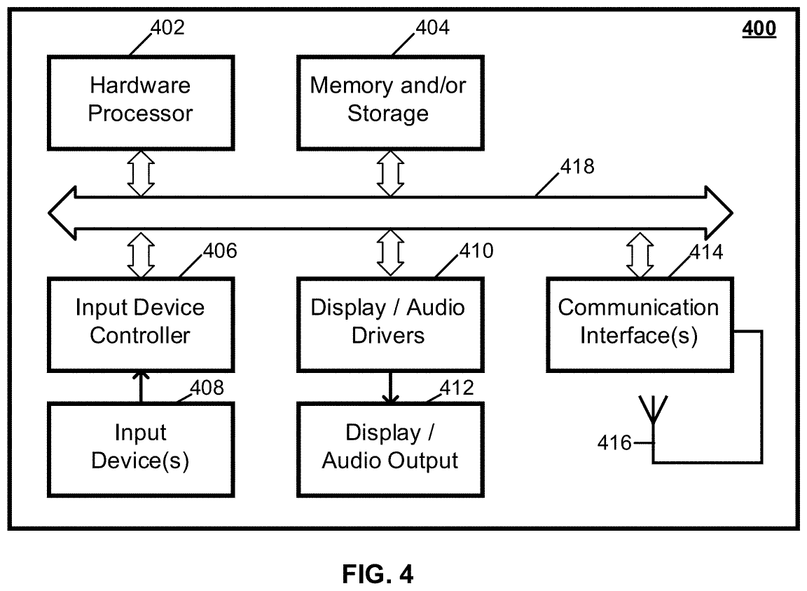

Server 302 and user devices 306 can be implemented using any suitable hardware in some embodiments. For example, in some embodiments, devices 302 and 306 can be implemented using any suitable general-purpose computer or special-purpose computer. For example, a mobile phone may be implemented using a special-purpose computer. Any such general-purpose computer or special-purpose computer can include any suitable hardware. For example, as illustrated in example hardware 400 of FIG. 4, such hardware can include hardware processor 402, memory and/or storage 404, an input device controller 406, an input device 408, display/audio drivers 410, display and audio output circuitry 412, communication interface(s) 414, an antenna 416, and a bus 418.

Hardware processor 402 can include any suitable hardware processor, such as a microprocessor, a micro-controller, digital signal processor(s), dedicated logic, and/or any other suitable circuitry for controlling the functioning of a general-purpose computer or a special-purpose computer in some embodiments. In some embodiments, hardware processor 402 can be controlled by a server program stored in memory and/or storage of a server, such as server 302. In some embodiments, hardware processor 402 can be controlled by a computer program stored in memory and/or storage of a user device, such as user device 306. For example, in some embodiments, hardware processor 402 of user device 306 can cause user device 306 to execute a simulation, present a series of histograms indicating results of one or more simulations, and/or perform any other suitable function(s).

Memory and/or storage 404 can be any suitable memory and/or storage for storing programs, data, and/or any other suitable information in some embodiments. For example, memory and/or storage 404 can include random access memory, read-only memory, flash memory, hard disk storage, optical media, and/or any other suitable memory.

Input device controller 406 can be any suitable circuitry for controlling and receiving input from one or more input devices 408 in some embodiments. For example, input device controller 406 can be circuitry for receiving input from a touchscreen, from a keyboard, from one or more buttons, from a voice recognition circuit, from a microphone, from a camera, from an optical sensor, from an accelerometer, from a temperature sensor, from a near field sensor, from a pressure sensor, from an encoder, and/or any other type of input device.

Display/audio drivers 410 can be any suitable circuitry for controlling and driving output to one or more display/audio output devices 412 in some embodiments. For example, display/audio drivers 410 can be circuitry for driving a touchscreen, a flat-panel display, a cathode ray tube display, a projector, a speaker or speakers, and/or any other suitable display and/or presentation devices.

Communication interface(s) 414 can be any suitable circuitry for interfacing with one or more communication networks (e.g., computer network 304). For example, interface(s) 414 can include network interface card circuitry, wireless communication circuitry, and/or any other suitable type of communication network circuitry.

Antenna 416 can be any suitable one or more antennas for wirelessly communicating with a communication network (e.g., communication network 304) in some embodiments. In some embodiments, antenna 316 can be omitted.

Bus 418 can be any suitable mechanism for communicating between two or more components 402, 404, 406, 410, and 414 in some embodiments.

Any other suitable components can be included in hardware 300 in accordance with some embodiments.

In some embodiments, at least some of the above described blocks of the process of FIG. 1 can be executed or performed in any order or sequence not limited to the order and sequence shown in and described in connection with the figures. Also, some of the above blocks of FIG. 1 can be executed or performed substantially simultaneously where appropriate or in parallel to reduce latency and processing times. Additionally or alternatively, some of the above described blocks of the process of FIG. 1 can be omitted.

In some embodiments, any suitable computer readable media can be used for storing instructions for performing the functions and/or processes herein. For example, in some embodiments, computer readable media can be transitory or non-transitory. For example, non-transitory computer readable media can include media such as non-transitory forms of magnetic media (such as hard disks, floppy disks, and/or any other suitable magnetic media), non-transitory forms of optical media (such as compact discs, digital video discs, Blu-ray discs, and/or any other suitable optical media), non-transitory forms of semiconductor media (such as flash memory, electrically programmable read-only memory (EPROM), electrically erasable programmable read-only memory (EEPROM), and/or any other suitable semiconductor media), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Accordingly, methods, systems, and media for data visualization and navigation of multiple simulation results in urban design are provided.

Although the invention has been described and illustrated in the foregoing illustrative embodiments, it is understood that the present disclosure has been made only by way of example, and that numerous changes in the details of implementation of the invention can be made without departing from the spirit and scope of the invention. Features of the disclosed embodiments can be combined and rearranged in various ways.

What is claimed is:

1. A method for data visualization and navigation of multiple simulation results in urban design, the method comprising:
generating, using a hardware processor, a plurality of design options for a district in response to running a simulation using a set of received design inputs;
determining, using the hardware processor, a plurality of output values of the simulation for each parameter of a plurality of parameters that are associated with each of the plurality of design options;
generating, using the hardware processor, a plurality of histograms, wherein each histogram corresponds to a parameter from the plurality of parameters associated with each of the plurality of design options;
presenting, using the hardware processor, a user interface that includes the plurality of histograms, wherein one or more portions of each histogram in the user interface are user-selectable;
in response to receiving a user selection of a portion within a histogram corresponding to a parameter, presenting, using the hardware processor, the user selection of the portion in the histogram of the user interface and determining one or more output values of the parameter that correspond with the portion of the histogram from the plurality of output values; and
in response to determining the one or more output values of the parameter that correspond with the portion of the histogram, automatically modifying, using the hardware processor, a presentation of remaining histograms in the user interface to highlight a first subset of output values of other parameters in the remaining histograms that correspond with the one or more output values of the parameter and reduce an appearance of a second subset of output values of the other parameters in the remaining histograms that do not correspond with the one or more output values of the parameter.

2. The method of claim 1, wherein determining the plurality of output values further comprises querying a database of simulation outputs associated with each of the plurality of parameters.

3. The method of claim 1, wherein the user interface comprises an option to select a subset of parameters from the plurality of parameters for generating the plurality of histograms.

4. The method of claim 1, wherein each histogram in the plurality of histograms is generated using a t-distributed stochastic neighbor embedding technique.

5. The method of claim 1, wherein the user selection of the portion within the histogram is a user-selected point that corresponds to an output value within the histogram.

6. The method of claim 1, wherein the user selection of the portion within the histogram is a user-selected window that spans across multiple output values within the histogram.

7. The method of claim 1, further comprising:
receiving a second user selection of a second portion within a second histogram corresponding to a second parameter;
presenting the second user selection of the second portion in the second histogram corresponding to the second parameter and determining a third subset of output values of the second parameter from the first subset of output values in the second histogram of the second parameter that correspond with the second portion of the second histogram; and
automatically modifying the presentation of the remaining histograms in the user interface based on the third subset of output values of the second parameter.

8. A system for data visualization and navigation of multiple simulation results in urban design, the system comprising:
a memory; and
a hardware processor that, when configured to execute computer executable instructions stored in the memory, is configured to:
generate a plurality of design options for a district in response to running a simulation using a set of received design inputs;
determine a plurality of output values of the simulation for each parameter of a plurality of parameters that are associated with each of the plurality of design options;
generate a plurality of histograms, wherein each histogram corresponds to a parameter from the plurality of parameters associated with each of the plurality of design options;
present a user interface that includes the plurality of histograms, wherein one or more portions of each histogram in the user interface are user-selectable;
in response to receiving a user selection of a portion within a histogram corresponding to a parameter, present the user selection of the portion in the histogram of the user interface and determining one or more output values of the parameter that correspond with the portion of the histogram from the plurality of output values; and
in response to determining the one or more output values of the parameter that correspond with the portion of the histogram, automatically modify a presentation of remaining histograms in the user interface to highlight a first subset of output values of other parameters in the remaining histograms that correspond with the one or more output values of the parameter and reduce an appearance of a second subset of output values of the other parameters in the remaining histograms that do not correspond with the one or more output values of the parameter.

9. The system of claim 8, wherein determining the plurality of output values further comprises querying a database of simulation outputs associated with each of the plurality of parameters.

10. The system of claim 8, wherein the user interface comprises an option to select a subset of parameters from the plurality of parameters for generating the plurality of histograms.

11. The system of claim 8, wherein each histogram in the plurality of histograms is generated using a t-distributed stochastic neighbor embedding technique.

12. The system of claim 8, wherein the user selection of the portion within the histogram is a user-selected point that corresponds to an output value within the histogram.

13. The system of claim 8, wherein the user selection of the portion within the histogram is a user-selected window that spans across multiple output values within the histogram.

14. The system of claim 8, wherein the hardware processor is further configured to:
receive a second user selection of a second portion within a second histogram corresponding to a second parameter;
present the second user selection of the second portion in the second histogram corresponding to the second parameter and determining a third subset of output values of the second parameter from the first subset of output values in the second histogram of the second parameter that correspond with the second portion of the second histogram; and
automatically modify the presentation of the remaining histograms in the user interface based on the third subset of output values of the second parameter.

15. A non-transitory computer-readable medium containing computer executable instructions that, when executed by a processor, cause the processor to perform a method for data visualization and navigation of multiple simulation results in urban design, the method comprising:
generating, using a hardware processor, a plurality of design options for a district in response to running a simulation using a set of received design inputs;
determining, using the hardware processor, a plurality of output values of the simulation for each parameter of a plurality of parameters that are associated with each of the plurality of design options;
generating, using the hardware processor, a plurality of histograms, wherein each histogram corresponds to a parameter from the plurality of parameters associated with each of the plurality of design options;
presenting, using the hardware processor, a user interface that includes the plurality of histograms, wherein one or more portions of each histogram in the user interface are user-selectable;
in response to receiving a user selection of a portion within a histogram corresponding to a parameter, presenting, using the hardware processor, the user selection of the portion in the histogram of the user interface and determining one or more output values of the parameter that correspond with the portion of the histogram from the plurality of output values; and
in response to determining the one or more output values of the parameter that correspond with the portion of the histogram, automatically modifying, using the hardware processor, a presentation of remaining histograms in the user interface to highlight a first subset of output values of other parameters in the remaining histograms that correspond with the one or more output values of the parameter and reduce an appearance of a second subset of output values of the other parameters in the remaining histograms that do not correspond with the one or more output values of the parameter.

16. The non-transitory computer-readable medium of claim 15, wherein determining the plurality of output values further comprises querying a database of simulation outputs associated with each of the plurality of parameters.

17. The non-transitory computer-readable medium of claim 15, wherein the user interface comprises an option to select a subset of parameters from the plurality of parameters for generating the plurality of histograms.

18. The non-transitory computer-readable medium of claim 15, wherein each histogram in the plurality of histograms is generated using a t-distributed stochastic neighbor embedding technique.

19. The non-transitory computer-readable medium of claim 15, wherein the user selection of the portion within the histogram is a user-selected point that corresponds to an output value within the histogram.

20. The non-transitory computer-readable medium of claim 15, wherein the user selection of the portion within the histogram is a user-selected window that spans across multiple output values within the histogram.

21. The non-transitory computer-readable medium of claim 15, wherein the method further comprises:
receiving a second user selection of a second portion within a second histogram corresponding to a second parameter;
presenting the second user selection of the second portion in the second histogram corresponding to the second parameter and determining a third subset of output values of the second parameter from the first subset of output values in the second histogram of the second parameter that correspond with the second portion of the second histogram; and
automatically modifying the presentation of the remaining histograms in the user interface based on the third subset of output values of the second parameter.
